(19) United States
(12) Patent Application Publication
(10) Pub. No.: US 2006/0054921 A1
(43) Pub. Date: Mar. 16, 2006

(54) Light emitting diode

(75) Inventors: Tetsuroh Murakami, Tenri-shi (JP); Nobuyuki Watanabe, Nara-shi (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka (JP)

(21) Appl. No.: 11/221,920

(22) Filed: Sep. 9, 2005

(30) Foreign Application Priority Data
Sep. 13, 2004 (JP) P2004-265156

(51) Int. Cl. H01L 33/00

(52) U.S. Cl. 257/103

(57) ABSTRACT

The light emitting diode comprises a p-type AlGaInP active layer 15, a p-type GaAs contact layer for transparent electrode 17, and an ITO transparent electrode 110. The carrier concentration of the p-type GaAs contact layer 17 has been set to 1.0×1019 cm−3.

### CROSS-REFERENCE TO RELATED APLICATIONS

This nonprovisional application claims a right of priority on the basis of the application No.2004-265156 filed in Japan on Sep. 13, 2004, under 35 U.S.C. 119(a). The full disclosure of it is incorporated herein by reference.

### BACKGROUND OF THE INVENTION

The present invention relates to a light emitting diode widely used in display devices, etc., and more particularly to a light emitting diode in which AlGaInP is used as a material of the light emitting layer, and indium tin oxide (ITO) is used as a material of the transparent electrode.

The AlGaInP light emitting layer is capable of emitting from green light to red light according to its composition ratio. For this reason, a light emitting diode including the AlGaInP light emitting layer is used as an element for display. Furthermore, until now, various element structures of the light emitting diode have been implemented in order to increase the brightness of the light emitting diode.

Conventional light emitting diodes provided with an AlGaInP light emitting layer include a light emitting diode disclosed in Japanese Laid-Open Publication No.HEI-11-4020.

This light emitting diode comprises, as shown in FIG. 6, an n-type buffer layer 32, an n-type distributed Bragg reflector (DBR) film 33, an n-type AlInP clad layer 34, a p-type AlGaInP active layer 35, a p-type AlInP clad layer 36, a p-type contact layer for transparent electrode 37, an n-type current block layer 38, a Zn layer 39, and a transparent electrode 310 successively laminated on an n-type GaAs substrate 31.

The current block layer 38 is formed in the shape of a disk by photolithography to cover only the midsection of the contact layer 37.

The transparent electrode 310 is formed by a sputtering method.

The notation 311 denotes an electrode for wire bonding, and the notation 312 denotes an n-side electrode.

The light emitting diode configured as described above has a double hetero structure in which the active layer 35 is sandwiched between the clad layers 34 and 36, thereby improving the luminous efficiency of the active layer 35.

Furthermore, the current block layer 38 is formed between the active layer 35 and the electrode for wire bonding 311, thus preventing the light emitted by the active layer 35 from being absorbed by the electrode for wire bonding 311.

Furthermore, the transparent electrode 310 is formed under the electrode for wire bonding 311, thereby improving the diffusion of current from the electrode for wire bonding 311 to the active layer 35 to prevent the deterioration of the luminous efficiency caused by the concentration of current on part of the active layer 35.

Furthermore, the Zn layer 39 is provided between the transparent electrode 310 and the contact layer 37 in order to increase the degree of adhesion of the transparent electrode 310 to the contact layer 37.

However, the conventional light emitting diode described above has a problem that it is difficult to make ohmic contact between the contact layer 37 and the transparent electrode 310.

Furthermore, the Zn layer 39 becomes a light absorbing layer, thus deteriorating the light emission characteristic.

Furthermore, it is necessary to heat the substrate when the transparent electrode 310 is formed by a sputtering method, but heating the substrate crystallizes the material of the transparent electrode 310, and thereby it is difficult to process the transparent electrode 310.

### SUMMARY OF THE INVENTION

It is therefore an object of the present invention to provide a light emitting diode in which ohmic contact between a contact layer and a transparent electrode can be easily made.

In order to achieve the above object, there is provided a light emitting diode comprising a light emitting layer made of AlGaInP, a transparent electrode made of indium tin oxide, and a contact layer for the transparent electrode, wherein

the carrier concentration of the contact layer is not less than 1.0×1019 cm−3 and not more than 5.0×1019 cm−3.

According to the above light emitting diode, the characteristic of the contact between the contact layer and the transparent electrode has a correlation with the carrier concentration of the contact layer. When the carrier concentration of the contact layer is 1.0×1019 cm−3 or more, the ohmic contact between the contact layer and the transparent electrode can be easily made.

In addition, when the carrier concentration of the contact layer is 5.0×1019 cm−3 or less, the crystallinity of the contact layer can be prevented from deteriorating.

In one embodiment of the present invention, the contact layer is made of GaAs.

According to the above embodiment, the contact layer is made of GaAs, so that the ohmic contact between the contact layer and the transparent electrode can be easily made.

In one embodiment of the present invention, the contact layer is made of AlGaInP.

According to the above embodiment, the contact layer is made of AlGaInP, so that the ohmic contact between the contact layer and the transparent electrode can be easily made with reliability.

In one embodiment of the present invention, the carrier concentration of the contact layer is not less than 2.0×1019 cm−3 and not more than 3.0×1019 cm−3.

According to the above embodiment, when the carrier concentration of the contact layer is 2.0×1019 cm−3 or more, better ohmic contact between the contact layer and the transparent electrode can be easily made.

Furthermore, when the carrier concentration is 3.0×1019 cm−3 or less, the crystallinity of the light emitting layer can be prevented from deteriorating.

In the above embodiment, the thickness of the contact layer is not less than 0.01 μm and not more than 0.05 μm (500 Å).

In this embodiment, when the thickness of the contact layer is 0.05 μm or less, the absorption of light by the contact layer can be kept low. Thus, the optical output of the light emitting diode can be prevented from reducing.

Furthermore, when the thickness of the contact layer is 0.05 μm or less, the amount of diffusion of dopant from the contact layer to the light emitting layer is reduced, and thus the light emission characteristic can be kept in a good state.

Furthermore, when the thickness of the contact layer is 100 Å or more, the thickness can be easily controlled.

In one embodiment of the present invention, the transparent electrode is formed by a sputtering method after reverse sputtering is performed as a pretreatment.

According to the above embodiment, after reverse sputtering is performed as a pretreatment, the transparent electrode is formed by a sputtering method, so that the sheet resistance can be reduced.

In this connection, it is not desirable to form the transparent electrode by an evaporation method, because the evaporation method can not be performed subsequently to the reverse sputtering.

In one embodiment of the present invention, the sputtering method is a room temperature sputtering method without performing substrate heating.

According to the above embodiment, the sputtering method does not heat the substrate, so that the transparent electrode in amorphous state without being crystallized can be formed on the contact layer. Thus, the transparent electrode can be easily etched with, for example, hot phosphoric acid or the like.

In one embodiment of the present invention, the transparent electrode is annealed at a temperature not less than 300° C. and not more than 400° C. after being formed by the sputtering method.

According to the above embodiment, the transparent electrode formed by the sputtering method can be crystallized by the annealing at a temperature not less than 300° C. and not more than 400° C. Thus, the reliability of the ohmic contact between the contact layer and the transparent electrode can be increased.

In a light emitting diode according to the present invention, when the carrier concentration of the contact layer is 1.0×1019 cm−3 or more, the ohmic contact between the contact layer and the transparent electrode can be easily made.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 shows the relationship between reverse sputtering conditions and sheet resistances.

FIG. 2 shows the relationship between carrier concentrations of the contact layer and voltages at the current of 20 mA.

FIG. 3 shows the relationship between annealing conditions after room temperature sputtering and sheet resistances.

FIG. 4 is a schematic cross-sectional view of a light emitting diode according to the first embodiment of the present invention.

FIG. 5 is a schematic cross-sectional view of a light emitting diode according to the second embodiment of the present invention.

FIG. 6 is a schematic cross-sectional view of a conventional light emitting diode.

### DETAILED DESCRIPTION OF THE INVENTION

Pretreatments for sputtering of the ITO transparent electrode of a light emitting diode were investigated in the following way.

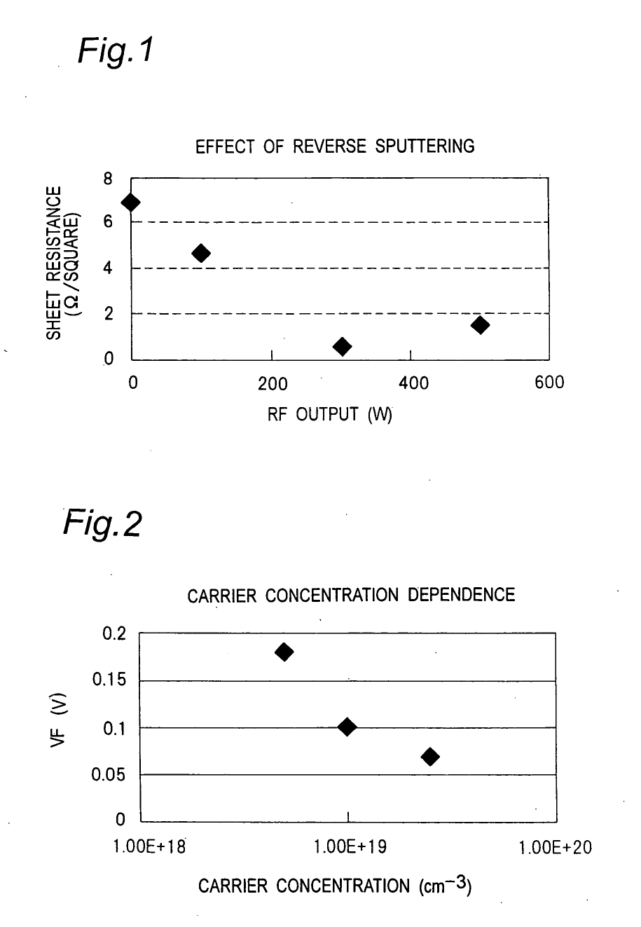

Comparison was made between the case of performing reverse sputtering as a pretreatment of sputtering on a p-type GaAs substrate having the carrier concentration of 1.0×1019 cm−3 and the case of not performing reverse sputtering as a pretreatment of sputtering on the substrate. Reverse sputtering was performed on three conditions that radio frequency (RF) outputs were 100 W, 300 W, and 500 W, respectively. After the reverse sputtering, an ITO transparent electrode was formed on the p-type GaAs substrate by 250° C. heat-sputtering, and then the sheet resistance was measured. The relationship between RF outputs of the reverse sputtering and sheet resistances was as shown in FIG. 1. As understood from FIG. 1, the sheet resistance in case that reverse sputtering was not performed is higher than those in case that the reverse sputtering was performed. When the reverse sputtering was performed, the sheet resistance at the RF output of 300 W is the lowest among sheet resistances at RF outputs of 100 W, 300 W, and 500 W. In this connection, when the reverse sputtering is performed on any appropriate condition, the sheet resistance can be reduced.

In addition, the relationship between carrier concentrations of the GaAs contact layer of a light emitting diode and forward voltages (VFs) of the diode was investigated in the following way.

A Zn-doped GaAs contact layer having the thickness of 400 Å was formed on a p-type GaAs substrate by a metal organic chemical vapor deposition (MOCVD) method. Three kinds of the GaAs contact layer having carrier concentrations of 2.5×1019 cm−3, 1.0×1019 cm−3, and 0.5×1019 cm−3, respectively, were formed. Reverse sputtering was performed at the RF output of 300 W, and then an ITO transparent electrode was formed on the GaAs contact layer by 250° C. heat-sputtering. After that, an AuZn electrode was evaporated onto the GaAs substrate and the ITO transparent electrode, and then the I-V contact characteristic was measured. VFs at the current value of 20 mA were as shown in FIG. 2. As understood from FIG. 2, the higher the carrier concentration of the GaAs contact layer, the easier the ohmic contact between the GaAs contact layer and the ITO electrode is made. For example, the VF (forward voltage) of a light emitting diode whose GaAs contact layer has the carrier concentration of 1.0×1019 cm−3 is only 0.1 V. Consequently, in order to reduce the operating voltage of the light emitting diode, the carrier concentration of the contact layer may be increased to, for example, 2.0×1019 cm−3, thus preventing the operating voltage from increasing.

In addition, sputtering conditions for the ITO transparent electrode of a light emitting diode were investigated in the following way.

Reverse sputtering at the RF output of 300 W was performed as a sputtering pretreatment on a p-type GaAs substrate having the carrier concentration of 1.0×1019 cm−3. After that, ITO transparent electrodes were formed by 250° C. heat-sputtering and room temperature sputtering, respectively, and then the sheet resistances were compared. The sheet resistance by the heat-sputtering was 0.56 Ω/square, while the sheet resistance by room temperature sputtering was 2.0 Ω/square. Thus, the sheet resistance by heating-sputtering is lower than that by room temperature sputtering.

In addition, conditions for annealing the ITO transparent electrode formed by room temperature sputtering were investigated.

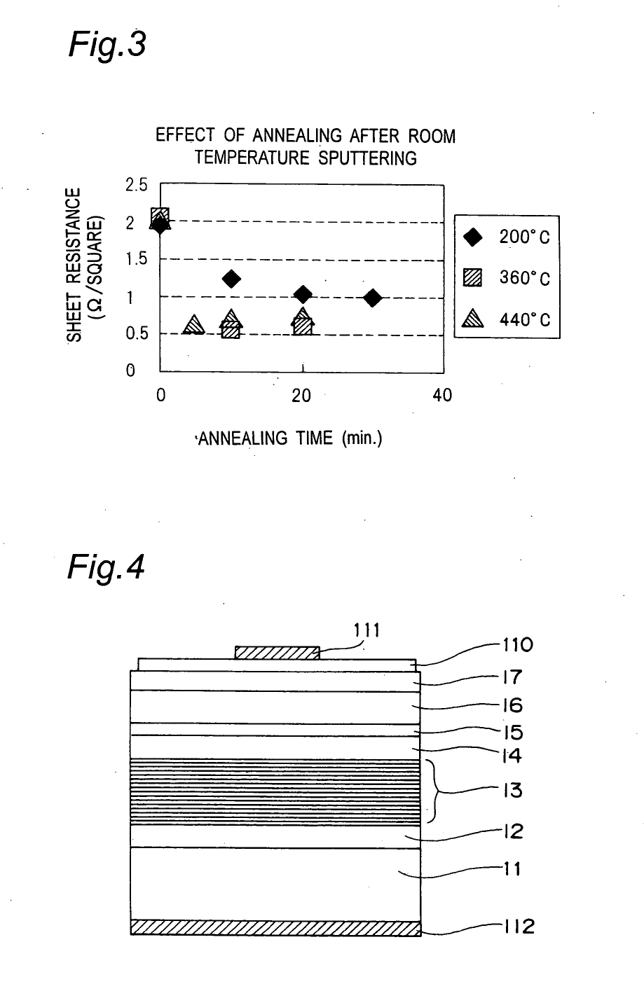

The result of the investigation of the conditions for the annealing is as shown in FIG. 3. As understood from FIG. 3, the lowest sheet resistance was obtained by annealing at 360° C. for 10 minutes. Although insufficient annealing or excess annealing causes a higher sheet resistance, the sheet resistance can be decreased by annealing on an appropriate condition. Consequently, when an ITO transparent electrode is annealed, even if it is formed by room temperature sputtering, the sheet resistance can be reduced to the same level as the ITO transparent electrode formed by heat-sputtering.

Furthermore, when investigating wet etching performed for the ITO transparent electrode formed by room temperature sputtering, it was found that the ITO transparent electrode formed by room temperature sputtering can be easily etched with hot phosphoric acid at 70° C. In contrast to this, the ITO transparent electrode formed by heat-sputtering is crystallized and chemically stabilized, thereby being etched only with special etchant.

When the ITO transparent electrode formed by room temperature sputtering is annealed after a process such as patterning on it, the ITO transparent electrode is crystallized, thereby having the same reliability as the ITO transparent electrode formed by heat-sputtering.

The present invention will be described in detail below on the basis of the embodiments thereof shown in the drawings.

### (FIRST EMBODIMENT)

FIG. 4 is a schematic cross-sectional view of a light emitting diode according to the first embodiment of the present invention.

The light emitting diode comprises an n-type GaAs substrate 11, and an n-type GaAs buffer layer 12, an n-type DBR film 13 which is an example of reflecting film, an n-type AlInP first clad layer 14, a p-type AlGaInP active layer 15, a p-type AlInP second clad layer 15, a p-type GaAs contact layer for transparent electrode 17, and an ITO transparent electrode 110 successively formed on the n-type GaAs substrate 11.

Light emitted from the p-type AlGaInP active layer 15 passes through the ITO transparent electrode 110. That is, the ITO transparent electrode 110 is transparent to the wavelength of light emitted from the p-type AlGaInP active layer 15.

On the ITO transparent electrode 110, an electrode for wire bonding (p-side electrode) 111 made of Au is formed. The electrode for wire bonding 111 is formed in the shape of a disk to cover substantially the midsection only of the ITO transparent electrode 110.

Under the n-type GaAs substrate 11, an n-side electrode 112 made of AuGe is formed. The n-side electrode 112 covers the whole of the rear face of the n-type GaAs substrate 11 (the surface of the substrate opposite from the p-type AlGaInP active layer 15).

The light emitting diode is manufactured as follows.

At first, the n-type GaAs buffer layer 12, the DBR film 13, the n-type AlInP first clad layer 14 having the thickness of 1 μm, the p-type AlGaInP active layer 15 having the thickness of 1 μm, the p-type AlInP second clad layer 16 having the thickness of 1 μm, and the p-type GaAs contact layer for transparent electrode 17 having the thickness of 0.04 μm (400 Å) are successively laminated on the n-type GaAs substrate 11 by a MOCVD method.

The n-type GaAs substrate 11 has a plane direction which is inclined by the angle of 15° toward the [011] direction from the (100) plane.

The carrier concentration of the p-type GaAs contact layer for transparent electrode 17 has been set to 1.0×1019 cm−3.

The n-type DBR film 13 consists of, for example, 10 pairs of n-type GaAs and n-type In0.5Al0.5P.

Next, the rear face of the GaAs substrate 11 is polished to make the thickness of the GaAs substrate 11 about 100 μm, and then AuGe is evaporated onto the rear face of the GaAs substrate 11 to be alloyed with GaAs. As a result of this, the electrode 112 made of AuGe is obtained.

Next, reverse sputtering is performed on the surface of the p-type GaAs contact layer for transparent electrode 17 at the RF output of 300 W for 5 minutes, and then the ITO transparent electrode 110 is deposited on the surface of the p-type GaAs contact layer for transparent electrode 17 by room temperature sputtering without heating the substrate, and Au is evaporated onto the surface of the ITO transparent electrode 110.

The reverse sputtering and the room temperature sputtering are successively performed in a chamber the degree of vacuum of which has been set to 1×10−6 torrs. Furthermore, the reverse sputtering and the room temperature sputtering are performed while introducing Ar gas into the chamber and setting the pressure in the chamber to 3×10−3 torrs.

Next, patterning is made on the Au to form the electrode for wire bonding 111 substantially shaped like a disk.

Next, the ITO transparent electrode 110 is etched with hot phosphoric acid at 70° C. to form dicing lines on the ITO transparent electrode 110.

Next, the ITO transparent electrode 110 is annealed at 360° C. for 10 minutes. As a result of this, the ITO transparent electrode 110 is crystallized.

Lastly, when the GaAs substrate 11 is divided by dicing, chip-shaped light emitting diodes are obtained.

In a light emitting diode thus manufactured, VF at the current of 20 mA is 2.2 V, and the ITO transparent electrode 110 is in good contact with the p-type GaAs contact layer for transparent electrode 17.

The ITO transparent electrode 110 formed by room temperature sputtering is easily patterned in contrast to an ITO transparent electrode formed by heat-sputtering. Thus, a complicated electrode pattern such as a two-wire type chip can be formed on the ITO transparent electrode 110.

Furthermore, when the ITO transparent electrode 110 is annealed at a temperature not less than 300° C. and not more than 400° C. after patterning, it may have a crystallinity similar to that of an ITO transparent electrode formed by heat-sputtering.

In the first embodiment, the p-type GaAs contact layer for transparent electrode 17 having the carrier concentration of 1.0×1019 cm−3 is used, but a p-type GaAs contact layer for transparent electrode having a carrier concentration more than 1.0×1019 cm−3 and not more than 5.0×1019 cm−3 may be used.

In the first embodiment, an n-type substrate is used, but a p-type substrate may be used. In case that a p-type substrate is used, an n-type GaAs contact layer for transparent electrode having a carrier concentration not more than 1.0×1019 cm−3 and not less than 5.0×1019 cm−3 may be used.

The thickness of the contact layer is preferably not less than 0.01 μm and not more than 0.05 μm.

### (SECOND EMBODIMENT)

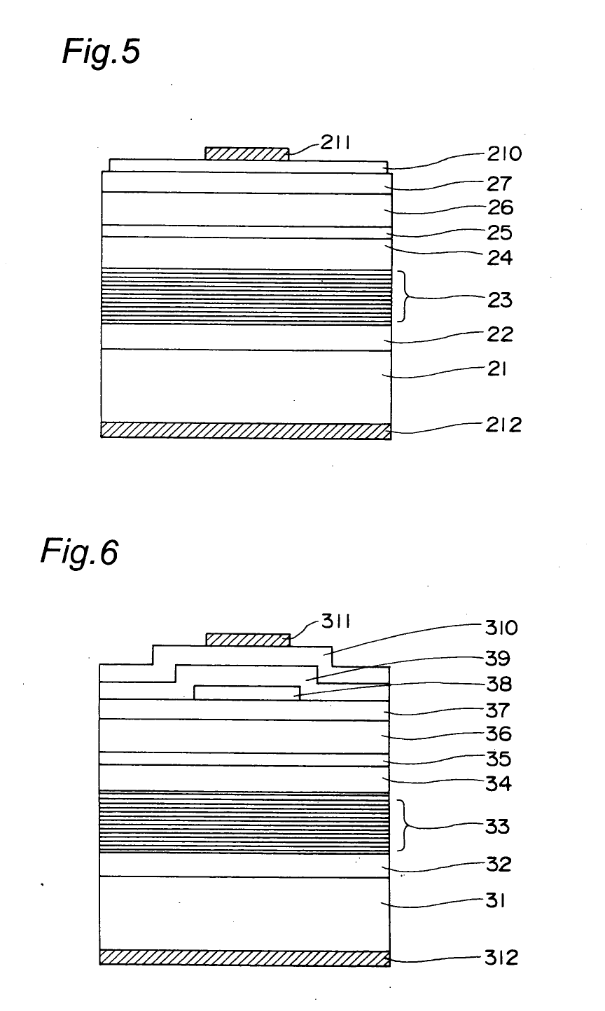

FIG. 5 is a schematic cross-sectional view of a light emitting diode according to the second embodiment of the present invention.

The light emitting diode comprises an n-type GaAs substrate 21, and an n-type GaAs buffer layer 22, an n-type DBR film 23 which is an example of reflecting film, an n-type AlInP first clad layer 24, a p-type AlGaInP active layer 25, a p-type AlInP second clad layer 26, a p-type (Al0.15Ga0.85)0.5In0.5P contact layer for transparent electrode 27, and an ITO transparent electrode 210 successively formed on the n-type GaAs substrate 21.

Light emitted from the p-type AlGaInP active layer 25 passes through the ITO transparent electrode 210. That is, the ITO transparent electrode 210 is transparent to the wavelength of light emitted from the n-type AlGaInP active layer 25.

On the ITO transparent electrode 210, an electrode for wire bonding (p-side electrode) 211 made of Au is formed. The electrode for wire bonding 211 is formed in the shape of a disk to cover substantially the midsection only of the ITO transparent electrode 210.

Under the n-type GaAs substrate 21, an n-side electrode 212 made of AuGe is formed. The n-side electrode 212 covers the whole of the rear face of the n-type GaAs substrate 21 (the surface of the substrate opposite from the p-type AlGaInP active layer 25).

The light emitting diode is manufactured as follows.

At first, the n-type GaAs buffer layer 22, the DBR film 23, the n-type AlInP first clad layer 24 having the thickness of 1 μm, the p-type AlGaInP active layer 25 having the thickness of 1 μm, the p-type AlInP second clad layer 26 having the thickness of 1 μm, and the p-type (Al0.15Ga0.85)0.5In0.5P contact layer for transparent electrode 27 having the thickness of 0.2 μm (2000 Å) are successively laminated on the n-type GaAs substrate 21 by a MOCVD method.

The n-type GaAs substrate 21 has a plane direction which is inclined by the angle of 15° toward the [011] direction from the (100) plane.

The carrier concentration of the p-type (Al0.15Ga0.85)0.5In0.5P contact layer for transparent electrode 27 has been set to 1.0×1019 cm−3.

The n-type DBR film 23 consists of, for example, 10 pairs of n-type GaAs and n-type In0.5Al0.5P.

Next, the rear face of the GaAs substrate 21 is polished to make the thickness of the GaAs substrate 21 about 100 μm, and then AuGe is evaporated onto the rear face of the GaAs substrate 21 to be alloyed with GaAs. As a result of this, the electrode 212 made of AuGe is obtained.

Next, reverse sputtering is performed on the surface of the p-type (Al0.15Ga0.85)0.5In0.5P contact layer for transparent electrode 27 at the RF output of 300 W for 5 minutes, and then the ITO transparent electrode 210 is deposited on the surface of the p-type (Al0.15Ga0.85)0.5In0.5P contact layer for transparent electrode 27 by room temperature sputtering without heating the substrate, and Au is evaporated onto the surface of the ITO transparent electrode 210.

The reverse sputtering and the room temperature sputtering are successively performed in a chamber the degree of vacuum of which has been set to 1×10−6 torrs. Furthermore, the reverse sputtering and the room temperature sputtering are performed while introducing Ar gas into the chamber and setting the pressure in the chamber to 3×10−3 torrs.

Next, patterning is made on the Au to form the electrode for wire bonding 211 substantially shaped like a disk.

Next, the ITO transparent electrode 210 is etched with hot phosphoric acid at 70° C. to form dicing lines on the ITO transparent electrode 210.

Next, the ITO transparent electrode 210 is annealed at 360° C. for 10 minutes. As a result of this, the ITO transparent electrode 210 is crystallized.

Lastly, when the GaAs substrate 21 is divided by dicing, chip-shaped light emitting diodes are obtained.

In a light emitting diode thus manufactured, VF at the current of 20 mA is 2.4 V, and the ITO transparent electrode 210 is in good contact with the p-type (Al0.15Ga0.85)0.5In0.5P contact layer for transparent electrode 27.

Furthermore, the optical output of the light emitting diode is 5% larger than that of the first embodiment.

The reason why the VF of the light emitting diode is larger than that of the first embodiment is that the contact resistance between the p-type (Al0.15Ga0.85)0.5In0.5P contact layer for transparent electrode 27 and the ITO transparent electrode 210 is a little larger than that of the first embodiment. However, the VF of 2.4 V of the light emitting diode is a level having no problem in practical use.

Furthermore, the reason why the optical output of the light emitting diode is larger than that of the first embodiment is that the optical absorption of the p-type (Al0.15Ga0.85)0.5In0.5P contact layer for transparent electrode 27 is less than the optical absorption of the p-type GaAs contact layer for transparent electrode 17.

The ITO transparent electrode 210 formed by room temperature sputtering is easily patterned in contrast to an ITO transparent electrode formed by heat-sputtering. Thus, a complicated electrode pattern such as a two-wire type chip can be formed on the ITO transparent electrode 210.

Furthermore, when the ITO transparent electrode 210 is annealed at a temperature not less than 300° C. and not more than 400° C. after patterning, it may have a crystallinity similar to that of an ITO transparent electrode formed by heat-sputtering.

In the second embodiment, the p-type (Al0.15Ga0.85)0.5In0.5P contact layer for transparent electrode 27 having the carrier concentration of 1.0×1019 cm−3 is used, but a p-type (Al0.15Ga0.85)0.5In0.5P contact layer for transparent electrode having a carrier concentration not less than 1.0×1019 cm−3 and not more than 5.0×1019 cm−3 may be used.

In the second embodiment, an n-type substrate is used, but a p-type substrate may be used. In case that a p-type substrate is used, an n-type (Al0.15Ga0.85)0.5In0.5P contact layer for transparent electrode having a carrier concentration not less than 1.0×1019 cm−3 and not more than 5.0×1019 cm−3 may be used.

The thickness of the contact layer is preferably not less than 0.01 μm and not more than 0.3 μm.

A light emitting diode according to the present invention is not limited to one having a double hetero structure, and may be one in which, for example, a single hetero structure, a quantum well junction structure, a homozygous structure, or the like is formed.

The invention being thus described, it will be obvious that the same may be modified in many ways. Such modifications are not to be regarded as a departure from the spirit and scope of the invention, and all improvements as would be obvious to one skilled in the art are intended to be included within the scope of the following claims.

What is claimed is:

1. A light emitting diode comprising a light emitting layer made of AlGaInP, a transparent electrode made of indium tin oxide, and a contact layer for the transparent electrode, wherein
the carrier concentration of the contact layer is not less than 1.0×1019 cm−3 and not more than 5.0×1019 cm−3.

2. The light emitting diode as claimed in claim 1, wherein
the contact layer is made of GaAs.

3. The light emitting diode as claimed in claim 1, wherein
the contact layer is made of AlGaInP.

4. The light emitting diode as claimed in claim 1, wherein
the carrier concentration of the contact layer is not less than 2.0×1019 cm−3 and not more than 3.0×1019 cm−3.

5. The light emitting diode as claimed in claim 1, wherein
the transparent electrode is formed by a sputtering method after reverse sputtering is performed as a pretreatment.

6. The light emitting diode as claimed in claim 5, wherein
the sputtering method is a room temperature sputtering method without performing substrate heating.

7. The light emitting diode as claimed in claim 6, wherein
the transparent electrode is annealed at a temperature not less than 300° C. and not more than 400° C. after being formed by the sputtering method.
